(19) United States
(12) Patent Application Publication
(10) Pub. No.: US 2026/0082867 A1
(43) Pub. Date: Mar. 19, 2026

(54) TRANSISTOR NANO CHANNEL THICKNESS MEASUREMENT TECHNIQUES AND APPARATUSES

(71) Applicant: Intel Corporation, Santa Clara, CA (US)

(72) Inventors: Aritra MANDAL, Beaverton, OR (US); Ayan DAS, Beaverton, OR (US); Navnit AGARWAL, Portland, OR (US)

(21) Appl. No.: 18/888,558

(22) Filed: Sep. 18, 2024

(51) Int. Cl. H01L 21/66; G01B 11/06; G01N 21/65; H01L 21/67; H01L 29/06; H01L 29/66

(52) U.S. Cl. CPC H10P 74/203; G01B 11/06; G01N 21/65; H10D 30/014; H10D 62/118; G01B 2210/56; H10P 72/0418

(57) ABSTRACT

Disclosed are techniques for fabricating transistors such as gate all around (GAA) transistors and techniques for measuring nano channel thicknesses using Raman spectroscopy.

### TECHNICAL FIELD

Embodiments of the invention relate to the field of semiconductor manufacturing; and more specifically, to fabricating transistors.

### BRIEF DESCRIPTION OF THE DRAWINGS

The disclosure may best be understood by referring to the following description and accompanying drawings that are used to illustrate embodiments of the invention. In the drawings:

FIG. 1 is a schematic perspective view of a gate all around (GAA) transistor in accordance with some embodiments.

FIG. 2 is a schematic diagram of a portion of a wafer processing apparatus with a Raman spectroscopy module in accordance with some embodiments.

FIG. 3 is a diagram showing exemplary Raman spectrum curve fits generated for a Raman spectra measurement taken on a part of a wafer after channel release in accordance with some embodiments.

FIG. 4 is a diagram showing Raman spectral shift channel-portion curves for three different wafer locations with different nano channel thicknesses in accordance with some embodiments.

FIG. 5A is a top schematic view of a wafer in accordance with some embodiments.

FIG. 5B is a magnified view of a wafer section from the wafer of FIG. 5A in accordance with some embodiments.

FIG. 6 is a flow diagram showing a routine 600 for measuring channel thicknesses in regions of a wafer in accordance with some embodiments.

FIG. 7A is a diagram showing exemplary process measurement sample sets in accordance with some embodiments.

FIG. 7B shows Raman curve width vs. channel thickness (TSi) relationships for different process types in accordance with some embodiments.

FIG. 8 is a picture showing a TEM image taken for measuring nano channel thicknesses in accordance with some embodiments.

FIG. 9 is a flow diagram showing a routine for fabricating gate all around (GAA) transistors in accordance with some embodiments.

FIGS. 10A-10E are schematic diagrams showing various stages of transistor fabrication in accordance with the routine of FIG. 9 in accordance with some embodiments.

### DETAILED DESCRIPTION

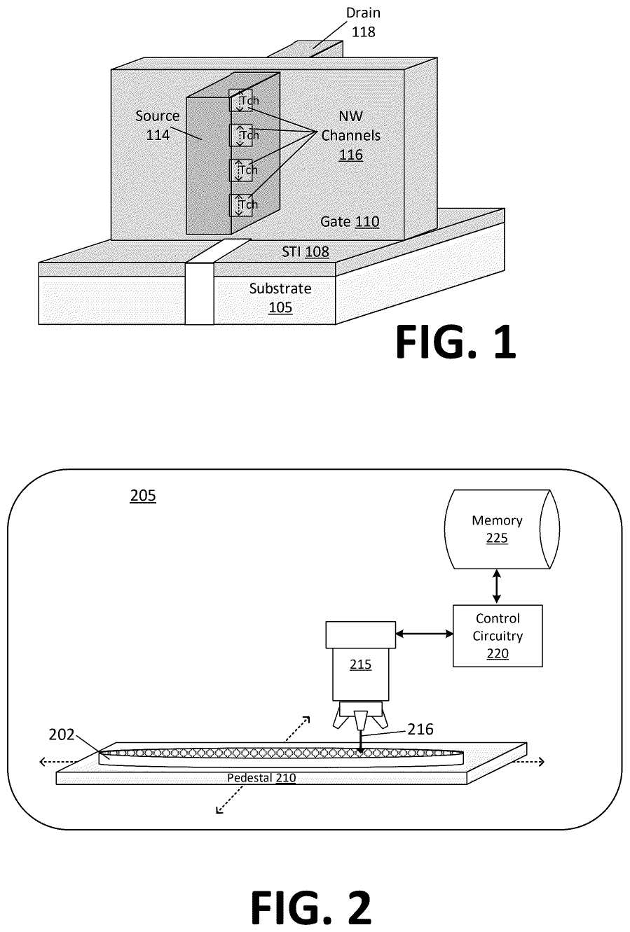

FIG. 1 is a schematic perspective view of a gate all around (GAA) transistor. The transistor is formed atop a wafer (or substrate) 105 and includes nanowire channels 116 that are surrounded by a gate structure 110 sitting on a shallow trench isolation (STI) layer 108. It also has a source 114 and a drain 118 that extend from the sides of the channels 116 as is shown.

As shown in the figure, GAA transistors feature a structure where the gate surrounds the channel on all sides, using stacked nanosheets (also referred to as nanowires, ribbons or simply nano channels). As compared with prior transistor designs, GAA transistors with their 360-degree gate coverage provide improved electrostatic control over the nano channels, reducing leakage currents and improving energy efficiency. They offer enhanced performance, allowing for higher drive currents and faster switching speeds. Moreover, their structural architectures enable continued transistor scaling to smaller dimensions, supporting the advancement of semiconductor technology into the angstrom era.

The channel dimensions are typically defined by three main parameters, channel width (e.g., similar to fin width for FinFET transistors), effective channel length, and the thickness (Tch) of the channels. Chipmakers can select the numbers and widths of utilized nano channels to control performance and power consumption for specific applications. For example, more and/or wider channels can result in stronger transistors with higher current carrying capabilities. For example, in order to achieve a given transistor strength, in some embodiments, three nano channels with wider and/or thinner dimensions may be used, while in other embodiments, four or more channels with narrower or thinner dimensions may be used. It should be appreciated that Raman measurement techniques described herein may be used for any of these configurations.

With many if not most implementations, variation of channel thickness (Tch) can significantly influence key transistor performance parameters like threshold voltage (VT) and are important for reliable gate control. The final Tch of the transistors are determined at channel release and channel trim, the steps where sacrificial material (e.g., Si—Ge) in the stack are removed. For example, when the channel thickness is targeted between 5 to 6 nm, sub-angstrom level variations in Tch can have strong influence on transistor performance. Therefore, an accurate inline metrology for monitoring Tch, e.g., with sub-angstrom level sensitivity, is desirable to achieve suitable process control in GAA transistor manufacturing.

Existing solutions for measuring Tch include optical critical dimensioning (OCD), which uses optical ellipsometry, and reciprocal space mapping X-Ray diffraction (XRD), both of which, however, have drawbacks. For example, they typically cannot provide accurate Tch measurements with angstrom level sensitivity. Moreover, Tch measurements using OCD are plagued with parasitic cross-correlation between other floating parameters. XRD could be a suitable technique, but generating smaller X-Ray beams sufficient to perform the measurements in active patterned devices is challenging without available or at least feasible solutions. Consequently, XRD based techniques may be used for un-patterned wafers but do not work for inline fabrication measurement processes.

Accordingly, in some embodiments, techniques employing Raman spectroscopy may be used to non-destructively measure GAA channel thicknesses with desired sensitivities. Raman spectral widths of channel vibrational modes in nano channels are reasonably dependent on Tch, especially in the thickness regimes of interest. As a result of phonon confinement effects, thinning of the nano channels broaden the Raman spectra of, for example, Si—Si vibrations. In some embodiments, this phenomenon is leveraged to measure Tch during channel release and/or channel trim processes. Since other channel dimensions do not materially influence the Raman spectral shift measurements, channel thickness (e.g., TSi for silicon channels) may be determined, or measured, based on measured Raman shifts.

Channel thickness measurements using measured Raman shift spectra can provide an efficient, non-destructive inline metrology solution for measuring Tch. Not only can such approaches be efficient and non-destructive, but also, they can be sensitive to angstrom-level Tch changes without being materially affected by changes in other transistor dimensions.

FIG. 2 is a schematic diagram of a portion of a wafer processing apparatus with a Raman spectroscopy module in accordance with some embodiments. For example, the depicted apparatus may be part of an etch tool in a semiconductor fabrication foundry. The apparatus 205 includes a controllably moveable pedestal 210 for supporting and adjusting the position of a semiconductor wafer 202 in order to process it. It also has a Raman spectroscopy assembly (or module) 215 including control circuitry 220 with memory 225 for controlling the spectroscopy assembly to perform Raman shift measurements on selected target areas of the wafer and determine channel thicknesses for transistors in those areas.

The control circuit 220 may be implemented with one or more processors, controllers, finite state machine circuits and/or combinations of the same. It may correspond to dedicated control circuitry for a Raman spectroscopy apparatus, itself, or it may be part of a semiconductor processing tool (e.g., etch control tool) having Raman measurement functionality included there within. As such, memory 225 has instructions that when executed by control circuit 220 control operation of the spectroscopy apparatus 220 to perform Raman based channel thickness measurements as discussed further below. The memory may also include Raman curve function data generated using techniques discussed below for different process types to perform inline, non-destructive Raman-based channel thickness measurements. In some embodiments, the control circuitry may also be coupled with control systems for controlling the X-Y position of pedestal 205 and/or the spectroscopy assembly 215 itself to measure different desired target areas on the wafer 202.

In operation, the spectroscopy assembly generates a laser beam 216 onto the selected target area and receives therefrom reflected back scattered Raman radiation that is processed and used to generate one or more Raman shift curves for the Raman shift measurement. Any suitable beam may be used. For example, in some embodiments, a laser generating a beam 216 having a 405 nm excitation wavelength and 0° co-polarization may be used. In some embodiments, the beam has an incident substantially circular cross-section with a diameter of 20 μm. Thus, the wafer area being measured has a surface of about 314 square micro-meters, which may cover thousands or more transistor structures being fabricated. Note that in the depicted embodiment, the beam has an incident angle of 90 degrees relative to the surface of the wafer but other angles may be used. In fact, incident angles of less than 90 degrees may be preferable in some implementations since they may yield higher portions of Raman scattering attributable to channel thicknesses as compared with the underlying bulk substrate.

The Raman spectroscopy assembly 215 uses intense light from the laser to probe the chemical bonds in the selected wafer area, generating a spectrum that is fitted into a curve and used to measure average channel thickness for devices within the incident beam area. The spectrometer assembly has three basic components (not specifically illustrated), a laser, a sample interface, and a spectrometer. The laser acts as an excitation source to provide the high intensity light used to obtain sufficient Raman signals for detection. For different specific materials, different wavelengths can be used, but scattering intensity is generally inversely proportional with the excitation wavelength, which means shorter laser wavelengths yield a greater Raman signal and vice versa. On the other hand, shorter wavelengths are more likely to induce autofluorescence than longer ones, which will obscure the Raman signal. Selecting a suitable laser wavelength therefore depends on sample type and measurement apparatus configuration. In some embodiments, a Raman system with a 405 nm wavelength may be used for measuring silicon channels formed on silicon substrates.

The Raman spectrometer system's sample interface refers to the optics which direct and focus the incident beam, and which collect the comparatively weak Raman emissions for routing to the spectrometer itself. A long-pass dichroic filter may be used to reflect shortwave laser light onto the wafer and to transmit Raman scattered light through to the spectrometer. An additional long-pass filter with a minimal optical density may also be integrated into the sampling optics to block Rayleigh scatter from the excitation laser light.

Any suitable optical structures may be employed. For example, some systems may use fiber optic coupling to allow the sampling optics to be integrated into a probe for use at a distance from the spectrometer, while others may use fully integrated sampling optics to reduce size and optical losses within the system.

The Raman spectrometer captures and detects the light reflected from the wafer interface, reporting a spectrum as a function of Raman shift relative to laser frequency. This typically relies on sufficient range, signal strength, and optical resolution. Key performance properties include high sensitivity, a good signal-to-noise ratio, and a high light collection power. Spectrometer range is another parameter to consider. This refers to the Raman shift frequency range, which typically covers the relevant shifting for the measured material of interest.

The Raman shift represents the difference in energy between the incident photons and the scattered photons. Shift is typically measured in units of wavenumbers, specifically inverse centimeters (cm−1). It is usually expressed as a shift in wavenumber from the excitation wavelength. For example, Raman shifts for silicon typically occur around 520 (cm−1). Using wavenumbers allows for convenient comparison of Raman spectra even when different laser excitation wavelengths are used. In some embodiments, Raman shift measurements may be taken for locations on a semiconductor wafer in order to generate a Raman shift curve for that location. As discussed in more detail below, the width of his curve is inversely correlated with the transistor channel thickness and thus can be used to measure channel thickness for transistors in that location.

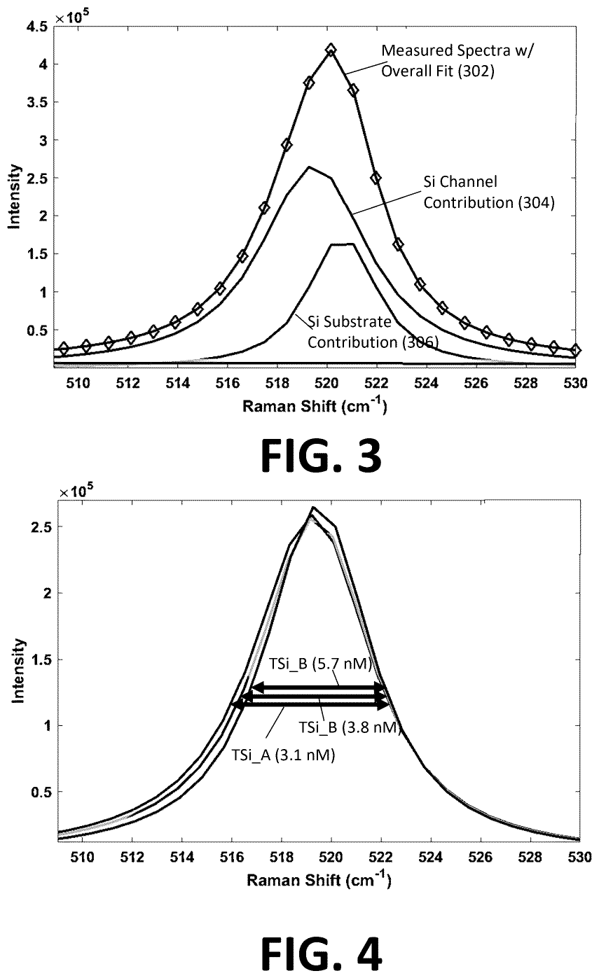

FIG. 3 is a diagram showing exemplary Raman spectrum curve fits generated for a Raman spectra measurement taken on a target area of a wafer after channel release. The measured part (target area) of the wafer had transistors with 26 nm wide silicon channels and a silicon substrate. A beam with a 405 nm excitation wavelength and 0° co-polarization configuration was used for this example. The figure shows three different curves: the overall spectra curve fit (302), the Si—Si vibrational channel portion curve fit (304), and the Si—Si vibrational silicon substrate curve fit (306). As can be seen, the shift for silicon is typically at 520 (cm−1). Once the channel-component curve has been extracted from the overall curve, it can be used to identify an average channel thickness for the measured wafer portion. The width of the Raman shift for the channel component is inversely proportional to the average thickness of the channels in the Raman spectra measurement zone and thus may be used to determine the average channel thicknesses.

In some embodiments, Lorentzian curve fitting techniques may be used to obtain the depicted Raman shift curves. Lorentzian curve fitting is commonly used in Raman spectroscopy analysis. It is characterized by sharp peaks in the center with long tails on either side. This shape often matches well with the natural line shape of Raman peaks. The goal of spectral curve fitting is to mathematically identify a peak, or peaks, that matches the measured Raman spectrum data. Lorentzian functions may be used as the basis for such a peak, examples of which are shown in FIG. 3.

In some embodiments, Lorentzian curve fitting for Raman analysis may be performed in the following manner. First, an initial peak position(s) may be identified, e.g., using a processor based peak-finding technique. The initial curve parameters including peak position, height, and width may then be estimated. Optimization techniques (e.g., Levenberg-Marquardt) may then be used to adjust these parameters and minimize the difference between the fitted curve and the original spectrum data. For channel measurements, peaks corresponding to the implemented channel (e.g., Si channel) should be identified and used.

It should be appreciated that while Lorentzian techniques may be used, mixed Gaussian-Lorentzian or even simply Gaussian or other profiles can alternatively be employed, e.g., when there's a combination of homogeneous and inhomogeneous broadening. In addition, spectroscopy software packages and programming libraries (e.g., SciPy in Python) may be used to more efficiently implement processing based curve fitting tasks.

FIG. 4 is a diagram showing Raman spectral shift channel-portion curves for three different wafer target areas with different nano channel thicknesses. As is illustrated, the curves correspond to channel with thicknesses of 3.1 nm (TSi_A), 3.8 nm (TSi_B) and 5.7 nm (TSi_C). (The channel thicknesses are indicated using “TSi” since the channels in this example are implemented with silicon.) The curve width measurements may be made from any suitable part of the curve. In the depicted embodiment, the widths are taken at half peak magnitudes of the curves. It can be seen that this half-peak curve width increases with decrease in channel thickness. In this example with a four channel GAA transistor, at 405 nm excitation, all four nanowires respond to the measured Raman spectra and hence this Raman spectral parameter responds to the average thickness of the four channels.

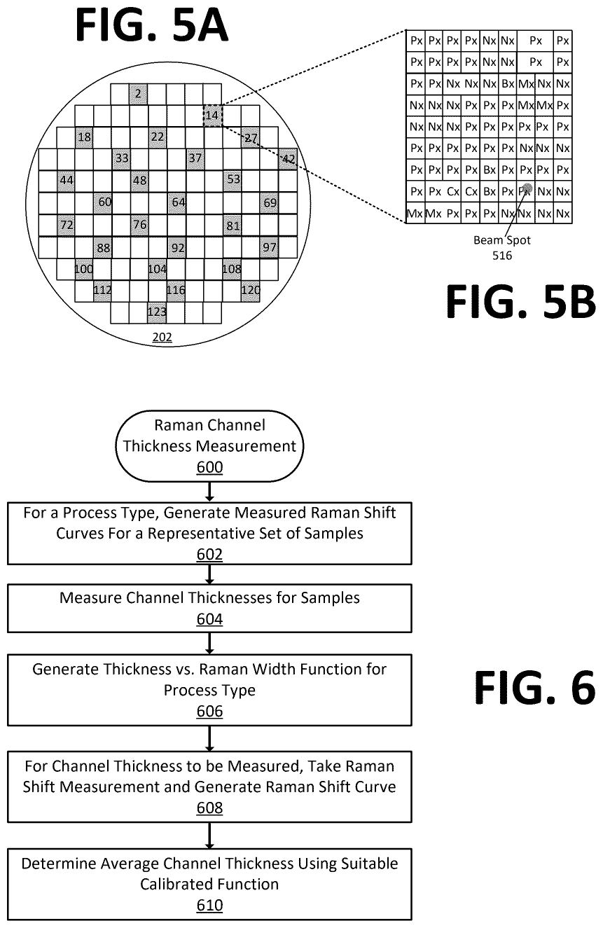

Reference is additionally made to FIGS. 5A and 5B, which show a top view of a wafer 202 having different die sections to be analyzed using Raman spectroscopy in accordance with some embodiments. FIG. 5A shows a wafer 202 that has a plurality of different sections each corresponding to one or more different integrated circuit (IC) chips. In turn, each of these sections may include a number of transistor type regions (also referred to as pads) of various different structures and/or process types.

FIG. 5B shows a magnified view of wafer section 14 from FIG. 5A. The magnified view illustrates a plurality of transistor type regions including different P-type transistor regions (Px), N-type transistor regions (Nx), regions used for memory (Mx) such as SRAM (static random access memory), bipolar devices (Bx) and other transistor types (Cx). The regions may occupy any of a variety of area sizes although a representative region may have an area of around 60×60 microns. With this example, a 20 micron Raman beam spot 516 is shown on a P-type (Px) region. Note that the spot spectroscopies are made, e.g., during and/or after channel release, to determine average channel thicknesses for the transistors contained under the Raman beam spot. This may correspond to thousands of different transistors whose average channel thicknesses are measured using the extracted Raman channel portion curve fit width.

FIG. 6 is a flow diagram showing a routine 600 for measuring channel thicknesses at target areas of a wafer in accordance with some embodiments. Initially, at 602, Raman shift curves are generated for a sufficient number of samples for different locations on one or more different wafers. For example, measurements for P-type transistors of a certain process type (channel dimensions, doping, etc.) may be made from different sections on a wafer and/or on different sections within different wafers.

In FIG. 5A, darkened sections represent sections that may be used for these samples. They are distributed over the entire wafer without requiring an excessive number of samples and curves to be generated. In some embodiments, sample sets may be obtained for one or for multiple different process types, e.g., for the different P-type processes, N-type process, memory transistor processes, etc. For each set of process type samples, curves are generated with channel portions extracted and fit into separate channel component curves such as is illustrated in FIG. 3.

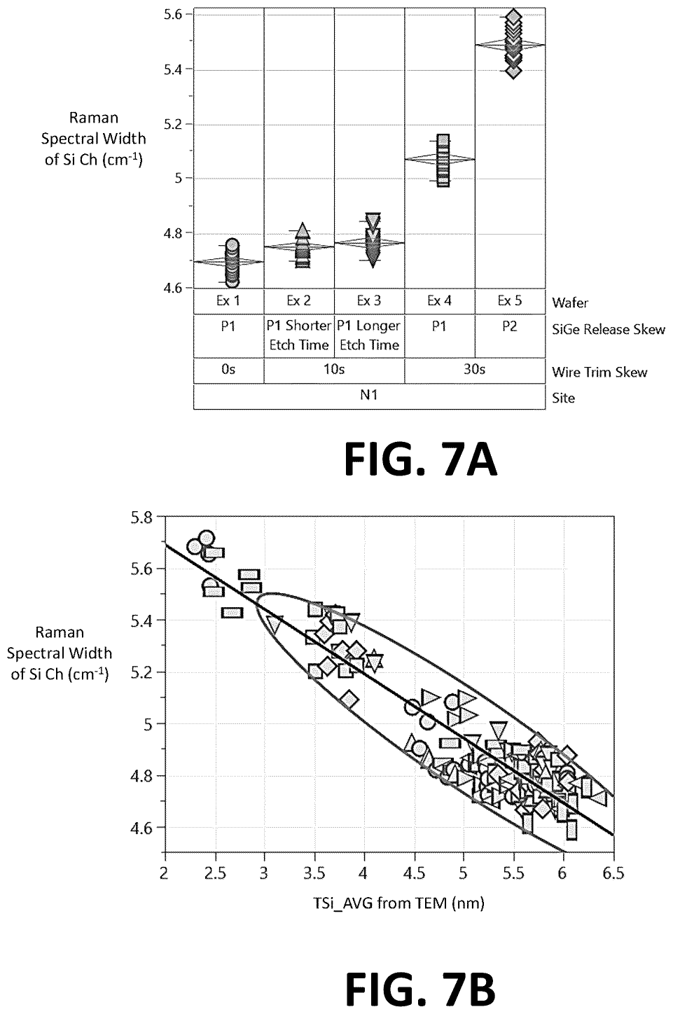

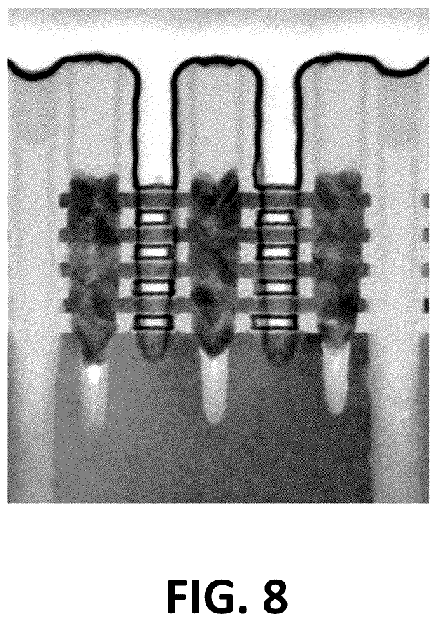

With additional reference to FIG. 7A, a diagram showing five different example process measurement sample sets (Ex 1-Ex 5) is shown. With this example, Raman channel component widths were taken for two different transistor process structure types (P1, P2) for different channel release (SiGe etch) and channel trim etch exposure times. It can be seen that the widths are primarily affected by channel trim exposure time being wider for longer trim times, corresponding to thinner Tch (i.e., TSi for the silicon nano channels). For a given channel release (SiGe etch) process, the etch time does not contribute much, if anything, to channel thickness, and hence, the Raman channel component curve Width does not meaningfully respond to these skews. However, channel thickness can be inherently different for different transistor structure and/or etch type processes. Therefore, Tch vs. Raman curve functions should be generated separately for like process structures and types. This is illustrated in FIG. 7B, which shows Raman curve widths vs. channel thicknesses (TSi) relationships for the different process type/conditions, indicated by different plotted shapes.

Returning to FIG. 6, at 604, the actual channel thicknesses for each of the Raman measured areas are measured. Any suitable method may be used. For example, transmission electron microscopy (TEM) or scanning electron microscopy (SEM) could be used to measure transistor channel thicknesses from cut-out cross-sectional samples taken from Raman measured target areas. FIG. 8 shows a TEM image taken for this purpose. It indicates the channel thicknesses (TSi_1-TSi_4) for the four separate channels.

At 606, for each measured process-type sample set, the Raman channel-portion curve widths are correlated, or associated, with the actual measured channel thicknesses in order to generate aggregate Raman channel thickness functions (thickness vs. Raman curve width functions). Curves themselves may be generated using interpolation and statistical linear curve generation techniques to create these functions. They may be implemented using any suitable computing techniques including but not limited to mathematical formulas, look-up tables, machine-learning models, and the like.

At 608, Raman measurements may be taken for channel thickness measurements for other wafers or wafer locations. For a measurement, a channel component Raman shift curve is generated. At 610, the average channel thickness for transistors in the measured Raman spot region (target area) is then determined by using an appropriate function (based on process type) to identify the thickness value based on the width of the Raman shift channel component curve.

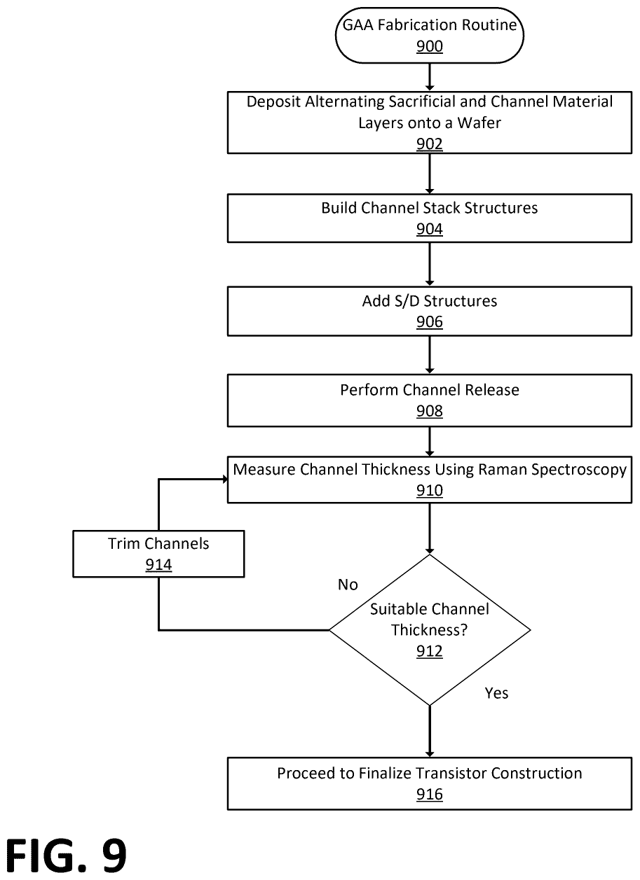

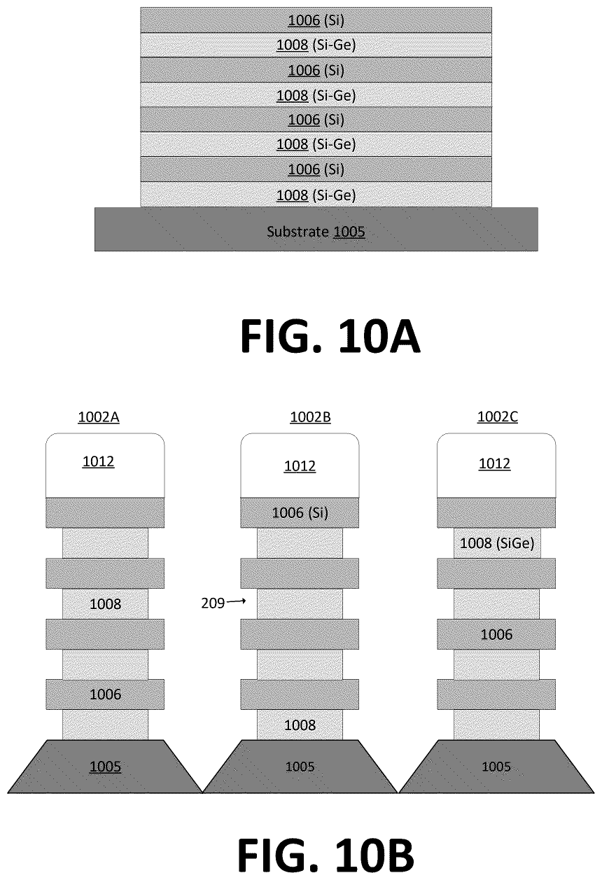

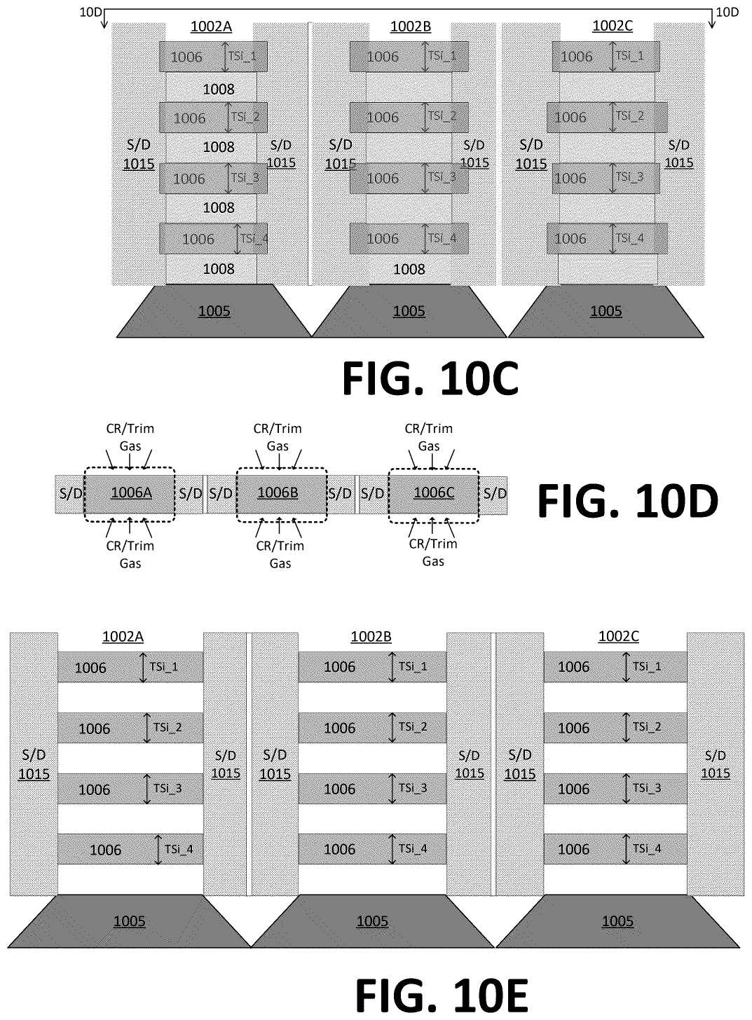

Reference is directed to FIG. 9 and FIGS. 10A to 10E. FIG. 9 is a flow diagram showing a routine 900 for fabricating gate all around (GAA) transistors in accordance with some embodiments. FIGS. 10A to 10E are schematic diagrams showing various stages of transistor fabrication in accordance with the flow routine of FIG. 9.

At 902 (FIG. 10A), alternating channel material layers 1006 and sacrificial material layers 1008 are deposited upon a substrate 1005. In the depicted embodiment, silicon is used for the channel layers 1006, silicon Germanium (Si—Ge) is used for the sacrificial layers 1008, and the substrate is formed from bulk silicon. Since with this embodiment, there will be four nano channels, four channel layers 1006 are formed. While Si and Si—Ge are used in this example for channel and sacrificial layers, respectively, it should be appreciated that any other materials or material combinations may be used depending, for example, on transistor type, process type and other considerations. For example, for better hole mobility, different channel/sacrificial stack materials may be used for N-type and P-type transistors. N-type stacks may alternate silicon and SiGe layers, while P-type stacks may use SiGe channels with SiGe sacrificial layers. For example, desired structure parameters may depend on the particular germanium sensitivity for a given etch process.

At 904 (FIG. 10B), channel stacks for individual transistors are formed. In this illustration, only three stacks (1002A, 1002B, 1002C) are shown but in a typical process, there would likely be billions or more transistor stacks being fabricated on the wafer for a given transistor process type. To do this, several process steps (not illustrated) may take place to arrive at the stacks seen in FIG. 10B. For example, once the alternating channel/sacrificial layers have been formed, they may be covered with a buffer oxide layer, a transfer layer and a mandrel layer (e.g., SiO₂, Si₃N₄, and Si, respectively).

Typically, the mandrel layer is patterned through etching, and silicon dioxide spacers are formed through anisotropic/isotropic over-etching. The spacer becomes the hard mask for etching the transfer layer and, in turn, the residual nitride of the transfer layer becomes the hard mask for etching the channel stacks. The part of silicon and silicon germanium not covered by the Si₃N₄ hard mask layer is etched. If a shallow trench isolation (STI) layer is to be used, it may then be formed on the bulk silicon on either sides of the channel stacks.

TEOS (tetraethyl Orthosilicate), or some other suitable material, may then be deposited onto the exposed structure and etched (e.g., through chemical mechanical polishing, CMP), and the Si—SiGe layers may then be oxidized to form an SiO₂ layer on the Si—SiGe layers. To form dummy gates (1012), polysilicon may then be deposited on the Si—SiGe layers and removed by means of photolithography where it doesn't cover the central part of the layers.

At 906, source and drain structures are grown and the dummy gates are removed. Before this happens, however, spacers and dielectric material may be deposited onto the dummy gates to be disposed between the gates and source/drain structures that are to be formed. Dielectric inner spacers are typically provided to isolate the gates from their source/drain regions. Using techniques like Low-Temperature Epitaxy (LTE), the source and drain structures are then grown from the exposed nanochannel ends. This growth process typically uses materials like SiGe for p-type devices or Si:P for n-type devices. The epitaxial growth process provides good contact between the channel and source/drain structures, and it allows for controlled doping of the source and drain. It can also be used to induce strain in the channel, enhancing carrier mobility. The growth can be tailored to optimize the trade-off between channel stress and parasitic resistance/capacitance. In some embodiments, alternative source/drain fabrication techniques may be used. For example, the sacrificial layers themselves may be used as doping sources for the source and drain regions, which can simplify the fabrication process while still achieving high performance. Once the source/drain structures are formed, the dummy gates (1012) may then be removed.

At 908 (FIGS. 10C, 10D), channel release is performed to remove the sacrificial layers (1008) and trim processes, if necessary, may also be performed on the nano channels. FIG. 10C is a side view showing the intact layers with S/D structures and without dummy gates, and FIG. 10D is a top view of FIG. 10C taken along line 10D-10D illustrating how the sacrificial and channel layers may be exposed to etch gas for channel release and channel trim.

The source/drain structures are protected during the channel release etch by the inner spacers and the S/D (e.g., epitaxial) material itself. This protection maintains the integrity of the source/drain structures while the sacrificial SiGe layers between the nano channels are being removed. The channel release etch process is designed to be highly selective, removing the sacrificial SiGe layers between the nano channels while leaving the material (e.g., SiGe) in the source/drain structures largely intact. This step exposes and releases the silicon channels, which are left suspended by the inner spacers and source/drain structures.

The channel release stage should be sufficiently selective for Si—Ge, meaning it can precisely etch Si—Ge layers while minimizing damage to adjacent silicon (Si) layers. The process should likely be isotropic, allowing for uniform etching, which is valuable for forming well-defined inner spacers and channels without damaging the surrounding material. The etching effectiveness is influenced by various parameters such as pressure, power, and other conditions. These parameters should be carefully controlled to achieve the desired etching results and ensure the integrity of the nano channel structures.

In some embodiments, selective etch tools (e.g., for lateral dry etching) may be used for this process. These tools can remove specific materials from most directions (isotropic etching) without damaging other parts of the device. The choice of gas depends on the desired etch characteristics and utilized structural materials. For example, chlorine-based gases can provide high selectivity for etching Ge over Si. Cl₂/N₂ gas mixtures may also be used to etch Si—Ge structures with anisotropic profiles. Other gases including fluorine-based gases e.g., SF₆ with added O₂) may be used for etching Si, Ge, and SiGe alloys. By adjusting the O₂ concentration, precision plasma etching of these materials may be achieved.

At 910, the channel thicknesses are measured using Raman techniques as described above and at 912, it is determined if they are at a desired (or suitable) value. In some embodiments, this measurement, alone or in combination with other test methods, may be used to determine if the sacrificial layers have been sufficiently removed. The thickness measurement alternatively, or in addition to, determines if the channels are at a desired average thickness, e.g., at a desired target value in a range of 3 to 7 nm.

If the thickness measurement indicates the channels are too thick, then at 914, additional etching is induced to trim the channels. The choice of etch process depends on several factors including etch profile (anisotropic or isotropic), process temperature, and etch rate control. Dry etching gases such as chlorine based chemistries (e.g., Cl, HCl) for anisotropic silicon etching or fluorine based chemistries (e.g., NF₃, CF₄) for isotropic etching may be employed. NF₃ in particular offers high selectivity and can be used at lower temperatures compared to traditional thermal processes. Hydrogen based chemistries (H₂, H₂/N₂ mixtures) can also be used for selective etching of SiGe layers in nano channel structures while preserving the Si layers. Any suitable combination of gases may be used in multi-step etch processes. For example, a chlorine-based chemistry might be used for initial anisotropic trimming followed by a fluorine-based isotropic etch for final shape refinement. The specific gas mixture and process parameters may be tuned for different applications to achieve the desired selectivity, etch profile and uniformity across the wafers being processed.

From here, the routine returns to 910 and measures the average channel thicknesses again. The routine proceeds as described until it is determined at 912 that the channels are at a suitable thickness. From here, it proceeds to 916 and completes transistor fabrication. Among other things, it may add operational gate layers and metal contacts.

Illustrative examples of the technologies disclosed herein are provided below. An embodiment of the technologies may include any one or more, and any compatible combination of, the examples described below.

Example 1 is an apparatus that includes a semiconductor processing tool and a control circuitry. The semiconductor processing tool includes a Raman spectrometer to generate Raman spectra data from a target area on a semiconductor wafer. The control circuit determines an aggregate channel thickness value for nano channels within the target area.

Example 2 includes the subject matter of example 1, and wherein the aggregate channel thickness value is an average thickness for the nano channels in gate all around (GAA) transistors in the target area.

Example 3 includes the subject matter of any of examples 1-2, and wherein the nano channels are silicon nano sheets.

Example 4 includes the subject matter of any of examples 1-3, and wherein the nano sheets are to have an average thickness value in a range of 3 to 6 nanometers.

Example 5 includes the subject matter of any of examples 1-4, and wherein the Raman spectra data is to be generated after a channel release stage and before an operational gate is formed around the nano channels.

Example 6 is a method for measuring nano channel thickness. The method includes measuring Raman shift spectra at a target area on a wafer that includes transistors with nano channels; determining a Raman shift channel-component width for the measured spectra; and generating an average thickness for the nano channels using a Raman channel thickness function for the transistors based on the Raman shift channel-component width.

Example 7 includes the subject matter of example 6, and wherein determining the Raman shift channel-component width comprises fitting an overall Raman shift curve for the measured spectra, extracting a channel-component Raman shift curve from the overall Raman shift curve, and deriving a width value from the channel-component Raman shift curve.

Example 8 includes the subject matter of any of examples 6-7, and wherein the width value is derived from the channel-component Raman shift curve at a half peak level of the channel-component Raman shift curve.

Example 9 includes the subject matter of any of examples 6-8, and wherein the act of measuring comprises measuring the Raman spectra at the area after sacrificial layers are etched away from the nano channels but before operational gate material is formed around the nano channels.

Example 10 includes the subject matter of any of examples 6-9, and wherein the sacrificial layers include silicon germanium.

Example 11 includes the subject matter of any of examples 6-10, and wherein the nano channels are formed from silicon.

Example 12 includes the subject matter of any of examples 6-11, and wherein the Raman channel thickness function is implemented as a mathematical operation by a control circuitry.

Example 13 includes the subject matter of any of examples 6-12, and wherein the Raman channel thickness function is implemented using a look-up table by a control circuitry.

Example 14 includes the subject matter of any of examples 6-13, and wherein the Raman channel thickness function is generated using a method comprising: (i) generating Raman Shift test curves for a sample set of different test areas on one or more test wafers, (ii) measuring test channel thicknesses in the test areas, and (iii) correlating the test curves with the measured test channel thicknesses to generate the Raman channel thickness function.

Example 15 is a computer readable storage medium having instructions that when executed by a processing system perform a method in accordance with any of examples 6-14.

Example 16 is a semiconductor etching apparatus, comprising a Raman spectroscopy instrument, a control circuitry, and a memory coupled to the control circuitry, the memory including instructions that when executed by the control circuitry cause it to control the etching apparatus to perform a method in accordance with the subject matter of any of examples 6-15 using the Raman spectroscopy instrument.

Example 17 is a method of fabricating transistors. The method includes depositing alternating layers of Sacrificial and channel material on a wafer; building a plurality of channel stack structures from the alternating sacrificial and channel material layers; adding source and drain structures to the channel stack structures; performing channel release etching to remove the sacrificial layer material; and measuring channel layer thickness using Raman spectroscopy.

Example 18 includes the subject matter of example 17, and comprising determining if the measured channel thickness is at a suitable value and trimming the channel layers until they are at a suitable thickness as determined from one or more additional Raman channel thickness measurements.

Example 19 includes the subject matter of any of examples 17-18, and further comprising adding operational gate structures to the channel layers when they are at the suitable thickness.

Example 20 includes the subject matter of any of examples 17-19, and wherein the sacrificial material includes silicon-germanium and the channel material includes silicon.

Example 21 includes the subject matter of any of examples 17-20, and wherein the act of depositing includes depositing at least three layers of channel material to form at least three nano channels for each transistor.

Example 22 includes the subject matter of any of examples 17-21, and wherein adding source and drain structures comprises epitaxially growing source and drain material from the channel layers.

Example 23 includes the subject matter of any of examples 17-22, and wherein measuring channel thickness includes measuring Raman shift spectra at a target area on the wafer; determining a Raman shift channel-component width for the measured spectra; and determining an average thickness for nano channels within the target area using a Raman channel thickness function for the transistors based on the Raman shift channel-component width.

Example 24 includes the subject matter of any of examples 17-23, and wherein determining the Raman shift channel-component width comprises fitting an overall Raman shift curve for the measured spectra, extracting a channel-component Raman shift curve from the overall Raman shift curve, and deriving a width value from the channel-component Raman shift curve.

Example 25 includes the subject matter of any of examples 17-24, and wherein the width value is derived from the channel-component Raman shift curve at a half peak level of the channel-component Raman shift curve.

Example 26 includes the subject matter of any of examples 17-25, and wherein the Raman channel thickness function is implemented as a mathematical operation by a control circuitry.

Example 27 includes the subject matter of any of examples 17-26, and wherein the Raman channel thickness function is implemented using a look-up table by a control circuitry.

Example 28 includes the subject matter of any of examples 17-27, and wherein the Raman channel thickness function is generated using a method comprising: (i) generating Raman Shift test curves for a sample set of different test areas on one or more test wafers, (ii) measuring test channel thicknesses in the test areas, and (iii) correlating the test curves with the measured test channel thicknesses to generate the Raman channel thickness function.

Example 29 is a computer readable storage medium having instructions that when executed by a processing system perform a method in accordance with the subject matter of any of examples 17-28.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth.

It should be appreciated that a processor or processor system may be implemented in various different manners. For example, it may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a semiconductor processing tool including a Raman spectrometer to generate Raman spectra data from a target area on a semiconductor wafer; and
a control circuit to determine an aggregate channel thickness value for nano channels in the target area.

2. The apparatus of claim 1, wherein the aggregate channel thickness value is an average thickness for the nano channels in gate all around (GAA) transistors in the target area.

3. The apparatus of claim 1, wherein the Raman spectra data is to be generated after a channel release stage and before an operational gate is formed around the nano channels.

4. A method for measuring nano channel thickness, comprising:
measuring Raman shift spectra at a target area on a wafer that includes transistors with nano channels;
determining a Raman shift channel-component width for the measured spectra; and
generating an average thickness for the nano channels using a Raman channel thickness function for the transistors based on the Raman shift channel-component width.

5. The method of claim 4, wherein determining the Raman shift channel-component width comprises fitting an overall Raman shift curve for the measured spectra, extracting a channel-component Raman shift curve from the overall Raman shift curve, and deriving a width value from the channel-component Raman shift curve.

6. The method of claim 5, wherein the width value is derived from the channel-component Raman shift curve at a half peak level of the channel-component Raman shift curve.

7. The method of claim 4, wherein the act of measuring comprises measuring the Raman spectra at the target area after sacrificial layers are etched away from the nano channels but before operational gate material is formed around the nano channels.

8. The method of claim 7, wherein the sacrificial layers include silicon germanium, and the nano channels are silicon.

9. The method of claim 4, wherein the Raman channel thickness function is implemented as a mathematical operation by a control circuitry.

10. The method of claim 4, wherein the Raman channel thickness function is implemented using a look-up table by a control circuitry.

11. The method of claim 4, wherein the Raman channel thickness function is generated using a method comprising: (i) generating Raman Shift test curves for a sample set of different test areas on one or more test wafers, (ii) measuring test channel thicknesses in the test areas, and (iii) correlating the test curves with the measured test channel thicknesses to generate the Raman channel thickness function.

12. A computer readable storage medium having instructions that when executed by a processing system perform the method of claim 4.

13. A semiconductor etching apparatus, comprising a Raman spectroscopy instrument, a control circuitry, and a memory coupled to the control circuitry, the memory including instructions that when executed by the control circuitry cause it to control the etching apparatus to perform the method of claim 4 using the Raman spectroscopy instrument.

14. A method of fabricating transistors, comprising:
depositing alternating layers of Sacrificial and channel material on a wafer;
building a plurality of channel stack structures from the alternating sacrificial and channel material layers;
adding source and drain structures to the channel stack structures;
performing channel release etching to remove the sacrificial layer material; and
measuring channel layer thickness using Raman spectroscopy.

15. The method of claim 14, comprising determining if the measured channel thickness is at a suitable value and trimming the channel layers until their thicknesses are at the suitable value as determined from one or more additional Raman channel thickness measurements.

16. The method of claim 15, comprising adding operational gate structures to the channel layers once they are at the suitable thickness value.

17. The method of claim 14, wherein the act of depositing includes depositing at least three layers of channel material to form at least three nano channels for each transistor.

18. The method of claim 14, wherein adding source and drain structures comprises epitaxially growing source and drain material from the channel layers.

19. The method of claim 14, wherein measuring channel thickness includes:
measuring Raman shift spectra at a target area on the wafer;
determining a Raman shift channel-component width for the measured spectra; and
determining an average thickness for nano channels within the target area using a Raman channel thickness function for the transistors based on the Raman shift channel-component width.

20. The method of claim 19, wherein determining the Raman shift channel-component width comprises fitting an overall Raman shift curve for the measured spectra, extracting a channel-component Raman shift curve from the overall Raman shift curve, and deriving a width value from the channel-component Raman shift curve.
